(19) United States
(12) Patent Application Publication
(10) Pub. No.: US 2025/0096079 A1
(43) Pub. Date: Mar. 20, 2025

(54) Semiconductor Device and Inverter Provided With Semiconductor Device

(71) Applicant: Hitachi Astemo, Ltd., Hitachinaka-shi, Ibaraki (JP)

(72) Inventors: Masahiro SEO, Chiyoda-ku, Tokyo (JP); Takeshi TOKUYAMA, Chiyoda-ku, Tokyo (JP); Takashi ISHII, Hitachinaka-shi, Ibaraki (JP)

(21) Appl. No.: 18/729,353

(22) PCT Filed: Dec. 27, 2022
(86) PCT No.: PCT/JP2022/048386

§ 371 Date: Jul. 16, 2024

(30) Foreign Application Priority Data
Jan. 20, 2022 (JP) 2022-007160

(51) Int. Cl. H01L 23/495; H01L 25/07; H02M 7/00

(52) U.S. Cl. CPC H01L 23/49531; H01L 25/072; H02M 7/003

(57) ABSTRACT

In this semiconductor device and the inverter provided with the semiconductor device, an upper arm semiconductor element on a positive electrode wiring plate and an AC wiring plate are connected to each other by a first wiring member, and a lower arm semiconductor element on the AC wiring plate and a negative electrode wiring plate are connected to each other by a second wiring member. The AC wiring plate has: a first region to which the first wiring member is to be connected; a second region in which the lower arm semiconductor element is to be provided; and a connection region that connects these two regions. The connection region is positioned opposite positive-electrode/negative-electrode terminals with a region in between where the first and second wiring members are used, and the placement order is as follows: the positive electrode wiring plate, the negative electrode wiring plate, the first region, and the second region.

### TECHNICAL FIELD

The present invention relates to a semiconductor device and an inverter provided with a semiconductor device.

### BACKGROUND ART

For the purpose of improving efficiency of an electric vehicle (EV) power train, an inverter using silicon carbide (Sic) that operates with a lower loss than silicon (Si) has been required.

SiC is required to be driven in a state where a large number of parallel chips are mounted because of two characteristics, high-speed switching and a small chip size. In this time, since parallel connection of numbers of chips makes a wiring length larger, there arises a problem that an inductance around a drain/source of a SiC chip increases to increase a loss. Furthermore, since current concentration also occurs due to variations in inductance, a structure of an inverter needs to have a low inductance for the purpose of suppressing a surge voltage at the time of switching. Furthermore, it is also necessary to achieve equal inductance between a plurality of SiC chips in order to suppress current concentration at the time of switching. In particular, single-sided direct-cooling type power module including a semiconductor device has wiring using wire bonding and a pattern of a ceramic substrate, and it is accordingly necessary to make each SiC chip have an equal inductance structure using such wiring.

As a background art of the present invention, Patent Literature 1 shown below discloses a configuration of an inverter in which an inductance is reduced by laminating patterns of a positive electrode and a negative electrode in a three-phase inverter.

### CITATION LIST

### Patent Literature

PTL 1: JP 2017-143219 A

### SUMMARY OF INVENTION

### Technical Problem

A configuration of the related art does not take into consideration that a plurality of semiconductor chips are arranged in parallel by one arm, and when the number of parallels of the chips is large (e.g., four or more parallels), a mounting region of the chips becomes wide to increase a wiring length accordingly. As a result, a wiring inductance increases to raise problems that a switching speed cannot be improved, and that a loss is increased. Furthermore, since a wiring length is different for each chip, there is a problem of difficulty in achieving both low inductance and equal inductance.

In view of this, an object of the present invention is to provide a semiconductor device that achieves both low inductance and equal inductance, and an inverter provided with a semiconductor device.

### Solution to Problem

A semiconductor device, and an inverter provided with a semiconductor device include, on an insulation layer of a substrate included in the semiconductor device: a positive electrode wiring board provided with a positive electrode terminal; a negative electrode wiring board provided with a negative electrode terminal; and an alternating-current wiring board provided with an alternating-current terminal, in which the positive electrode wiring board has a plurality of upper arm semiconductor elements electrically connected in parallel, the alternating-current wiring board has a plurality of lower arm semiconductor elements electrically connected in parallel, the plurality of upper arm semiconductor elements and the alternating-current wiring board being electrically connected to each other by first wiring members, respectively, and the plurality of lower arm semiconductor elements and the negative electrode wiring board being electrically connected to each other by second wiring members, respectively, the alternating-current wiring board has a first region to which the first wiring members are connected, a second region in which the plurality of lower arm semiconductor elements are provided, and a connection region that connects the first region and the second region, the connection region being provided at a position opposite to the positive electrode terminal and the negative electrode terminal with a region in between where the first wiring member connects the positive electrode wiring board and the first region and a region in between where the second wiring member connects the negative electrode wiring board and the second region, and the positive electrode wiring board, the negative electrode wiring board, the first region, and the second region are arranged on the insulation layer in the order of the positive electrode wiring board, the negative electrode wiring board, the first region, and the second region.

### Advantageous Effects of Invention

In view of this, the present invention enables provision of a semiconductor device that achieves both low inductance and equal inductance, and an inverter provided with the semiconductor device.

### BRIEF DESCRIPTION OF DRAWINGS

FIG. 1 shows an arrangement of a positive electrode terminal and a negative electrode terminal provided in a semiconductor device according to an embodiment of the present invention, and includes a cross-sectional view thereof taken along line A′-A.

FIG. 2 is a diagram for explaining a current direction at the positive electrode terminal and the negative electrode terminal in FIG. 1.

FIG. 3 is a diagram for explaining a connection member length of a wiring board according to the embodiment of the present invention.

FIG. 4 is a diagram for explaining an inverter system according to the embodiment of the present invention.

FIG. 5 is an electric circuit diagram of an inverter.

FIG. 6 is a view of an external appearance of the inverter.

In the following, an embodiment of the present invention will be described with reference to the drawings. The following description and drawings are examples for describing the present invention, and are appropriately omitted and simplified for the sake of clarity of the description. The present invention can be implemented in various other forms. Unless otherwise specified, each component may be singular or plural.

Positions, sizes, shapes, ranges, and the like of components illustrated in the drawings may not represent actual positions, sizes, shapes, ranges, and the like for the purpose of facilitating understanding of the invention. Therefore, the present invention is not necessarily limited to the positions, sizes, shapes, ranges, and the like disclosed in the drawings.

### EMBODIMENT OF PRESENT INVENTION AND OVERALL CONFIGURATION VIEW

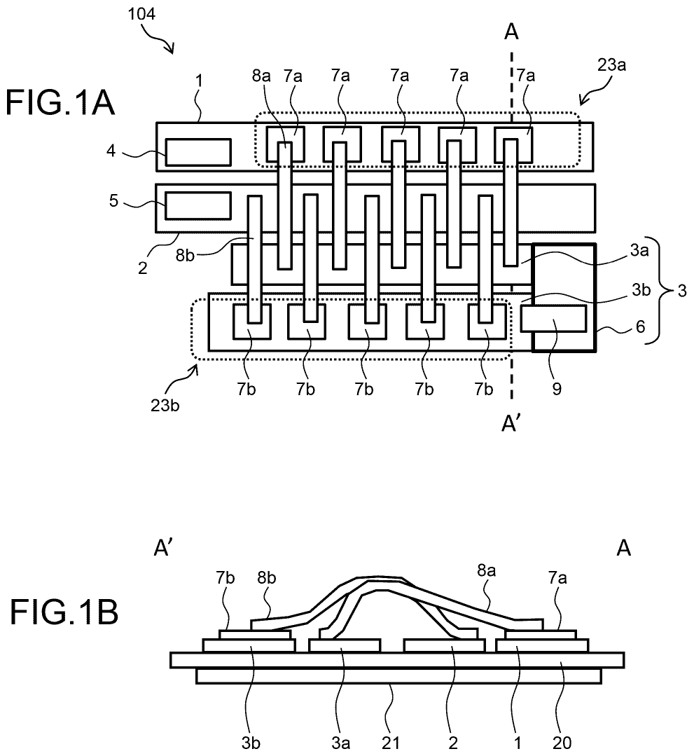

### (FIG. 1)

A basic configuration of a semiconductor device 104 will be described. The semiconductor device 104 has a positive electrode wiring board 1, a negative electrode wiring board 2, and an alternating-current wiring board 3. The positive electrode wiring board 1, the negative electrode wiring board 2, and the alternating-current wiring board 3 are arranged on an insulation layer 20 (FIG. 1(b)) on a ceramic substrate included in the semiconductor device 104. On the substrate of the semiconductor device 104, there is provided a conductor layer 21 (FIG. 1(b)) integrally arranged so as to cover the positive electrode wiring board 1, the negative electrode wiring board 2, and the alternating-current wiring board 3 with the insulation layer 20 interposed therebetween. Flow of an eddy current through the conductor layer 21 so as to cancel a magnetic flux generated by a current flowing through the positive electrode wiring board 1, the negative electrode wiring board 2, and the alternating-current wiring board 3 (a first region 3a and a second region 3b to be described later) reduces inductances of the positive electrode wiring board 1, the negative electrode wiring board 2, and the alternating-current wiring board 3.

The positive electrode wiring board 1 has the positive electrode terminal 4 and a plurality of semiconductor elements 7a which are semiconductor chips. The plurality of semiconductor elements 7a are arranged in a line on the positive electrode wiring board 1 along a longitudinal direction, thereby forming an upper arm semiconductor element 23a of the semiconductor device 104. The negative electrode wiring board 2 has a negative electrode terminal 5. The alternating-current wiring board 3 has the first region 3a, the second region 3b, and a connection region 6. The second region 3b has a plurality of semiconductor elements 7b which are semiconductor chips. The plurality of semiconductor elements 7b are arranged in a line on the second region 3b of the alternating-current wiring board 3 in the longitudinal direction, thereby forming a lower arm semiconductor element 23b of the semiconductor device 104. An alternating-current terminal 9 is arranged at a connection part between the second region 3b and the connection region 6.

The first region 3a and the second region 3b are connected by the connection region 6. As described above, since the first region 3a and the second region 3b divide an alternating-current wiring pattern at the connection region 6, a difference in inductance between the semiconductor elements 7a and 7b can be reduced.

A first wiring member 8a is connected to each semiconductor element 7a by wire bonding. Each first wiring member 8a connects the positive electrode wiring board 1 and the first region 3a. A second wiring member 8b is connected to each semiconductor element 7b by wire bonding. Each second wiring member 8b connects the negative electrode wiring board 2 and the second region 3b. Thus, the plurality of semiconductor elements 7a and the plurality of semiconductor elements 7b are electrically connected in parallel.

Since currents flowing through the first wiring member 8a and the second wiring member 8b, which are source wirings, are in opposite directions to each other, similarly to the currents flowing through the positive electrode wiring board 1, the negative electrode wiring board 2, the first region 3a, and the second region 3b, magnetic fluxes cancel out each other, so that inductances of the first wiring member 8a and the second wiring member 8b can be reduced. In addition, the first wiring members 8a and the second wiring members 8b are alternately arranged in parallel. In this way, as the number of configurations in which the wires 8a and 8b alternately intersect the wiring board increases, an effect of canceling out magnetic fluxes each other increases to enhance an effect of reducing the inductance.

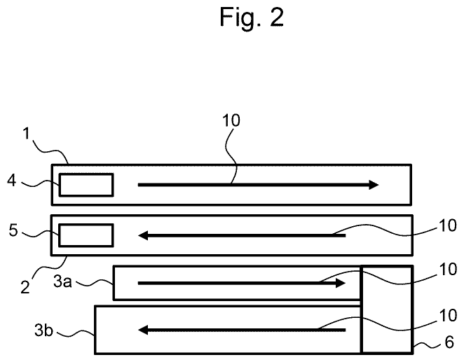

### (FIG. 2)

A current 10 in the positive electrode wiring board 1 and the first region 3a flows rightward, and a current 10 in the negative electrode wiring board 2 and the second region 3b flows leftward. Thus, by flowing the current 10 in an alternate direction on the wiring board, magnetic fluxes generated by adjacent currents can be canceled, and a mutual inductance (loop inductance) between the wiring boards can be reduced. In addition, by reducing the inductance, an effect of reducing a loss at the time of switching can be obtained, so that reliability is improved.

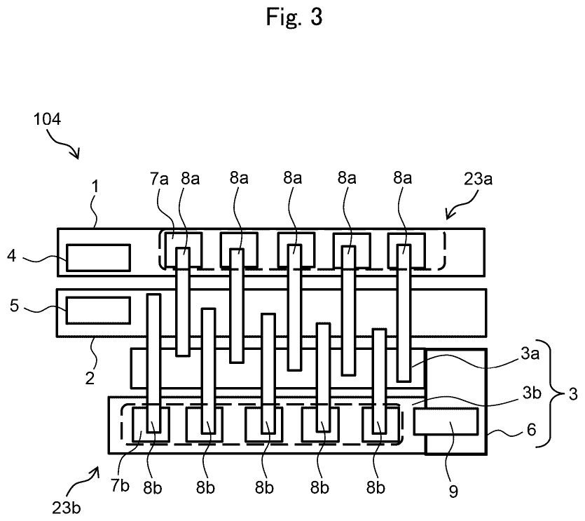

### (FIG. 3)

Although the configuration of the present invention has been described with reference to FIG. 1, a configuration in which lengths of the wires 8a and 8b are not unified but changed is further added. For example, the length of the wire 8a is made longer as the wire 8a is closer to the alternating-current terminal 9 which is a terminal on an emitter (a source in a case of MOS-FET) side of the semiconductor element 7a (made shorter as the wire 8a is farther from the alternating-current terminal 9).

This is because a magnitude of an emitter (source) inductance of each semiconductor element 7a in the semiconductor device 104 is a sum of inductances of the connected wire 8a and first region 3a, and inductances of the connected second region 3b and semiconductor element 7b. Specifically, since each semiconductor element 7a has a larger inductance of the first region 3a as the semiconductor element 7a is closer to the positive electrode terminal 4, each wire 8a is shortened as the wire 8a is closer to the positive electrode terminal 4 to reduce the inductance of the wire 8a, thereby equalizing a total of these inductances among the semiconductor elements 7a.

Similarly, with respect to an emitter (source) inductance of the semiconductor element 7b on the second region 3b, the length of the wire bonding 8b is made longer as the wire bonding 8b is closer to the negative electrode terminal 5 which is a terminal on the emitter (source) side of the semiconductor element 7b (made shorter as the wire bonding 8b is farther from the negative electrode terminal 5).

In this way, since the source inductance can be adjusted and the difference in source inductance between the semiconductor elements can be reduced, a current variation between the semiconductor elements at the time of switching is reduced, and the inductances can be equalized in line with an on-substrate source pattern. Furthermore, current concentration can be suppressed, and inductance reduction due to a current flow of a substrate pattern can be realized.

The alternating-current wiring board 3 has the first region 3a and the second region 3b, and is further provided with the connection region 6. The connection region 6 is provided at a position opposite to the positive electrode terminal 4 and the negative electrode terminal 5 with a region where the wires 8a and 8b connect the wiring boards provided therebetween. The positive electrode wiring board 1, the negative electrode wiring board 2, and the alternating-current wiring board 3 are arranged side by side in this arrangement order on the substrate of the semiconductor device 104. As a result, a mutual inductance between the wiring boards is reduced to reduce an inductance of the wiring board.

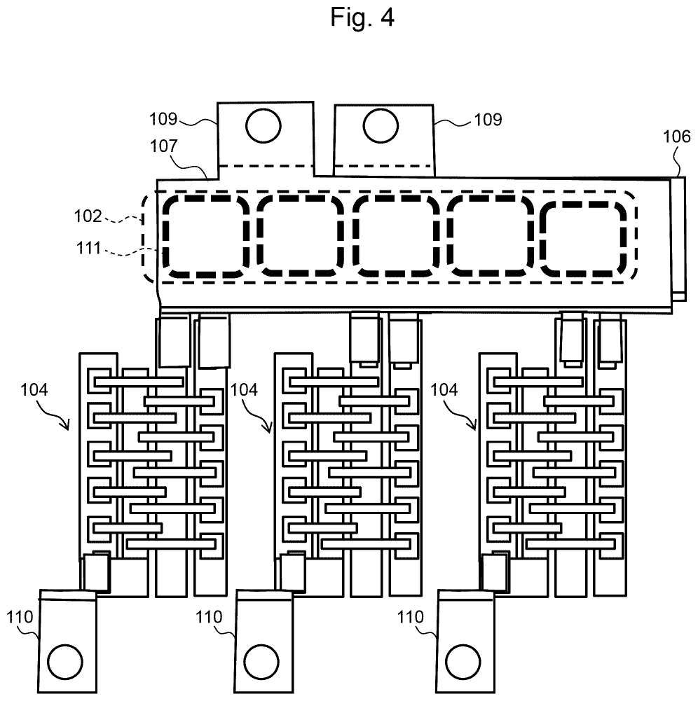

### (FIG. 4)

The three-phase semiconductor devices 104 are arranged side by side in parallel with a short-length direction (left-right direction in FIG. 4) of the respective semiconductor devices 104. In addition, a direct-current voltage input terminal 109 (high-voltage side input wiring 106, low-voltage side input wiring 107) and the semiconductor device 104 are connected via a smoothing capacitor 102 including film capacitors 111 arranged side by side in parallel along the direction in which the three-phase semiconductor devices 104 are arranged. The semiconductor device 104 is connected to a motor output terminal 110.

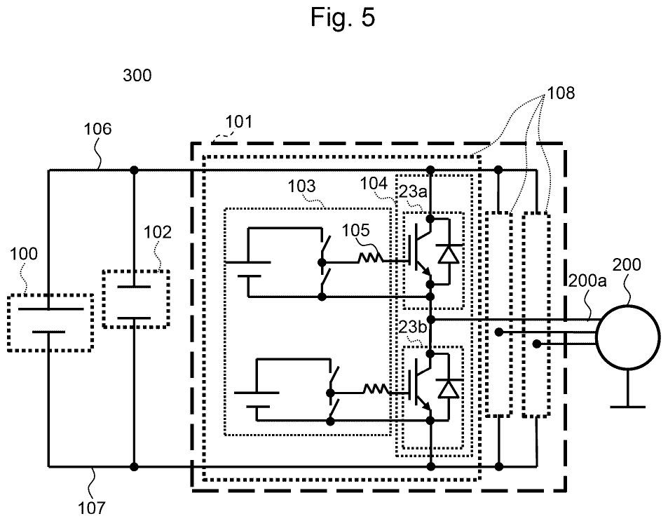

### (FIG. 5)

A three-phase inverter circuit 101 included in an inverter 300 is connected in parallel with a battery 100 and the smoothing capacitor 102, and is supplied with direct-current power from the battery 100. The direct-current power is smoothed by the smoothing capacitor 102 connected in parallel. The smoothed direct-current power is converted into alternating-current power by the semiconductor device 104 and output to a motor 200.

The three-phase inverter circuit 101 has a three-phase 1-leg inverter 108 that integrates the semiconductor device 104 and a control circuit 103, and outputs a three-phase alternating-current to the motor 200 by switching ON/OFF in the switching. In FIG. 5, only one phase is shown, and illustration of the other two phases is omitted.

A current flowing through the upper arm element 23a and the lower arm element 23b of the semiconductor device 104 is switched between ON and OFF in the switching described above by a control signal output from the control circuit 103. The control signal output from the control circuit 103 is input to each of the upper arm element 23a and the lower arm element 23b through a signal wiring and via a gate resistor 105.

The three-phase semiconductor device 104 is connected in parallel with the high-voltage side input wiring 106 and the low-voltage side input wiring 107. Furthermore, the three-phase inverter circuit 101 is connected to a three-phase stator winding 200a of the motor 200 at an intermediate point connected in series with each of the upper arm semiconductor element 23a and the lower arm semiconductor element 23b.

The three-phase semiconductor device 104 is connected in parallel with the high-voltage side input wiring 106 and the low-voltage side input wiring 107. Furthermore, with a signal wiring and a signal wiring board (not illustrated) of the semiconductor device 104, and the control circuit 103 provided, each of the upper arm semiconductor element 23a and the lower arm semiconductor element 23b is controlled by a signal input from the control circuit 103 via the signal wiring to function as the three-phase inverter circuit 101 which is an electric circuit device. Furthermore, the motor output terminal 110 (FIG. 4) and the three-phase stator winding 200a of the motor 200 are connected, the smoothing capacitor 102 is connected to the high-voltage side input wiring 106 and the low-voltage side input wiring 107, and the battery 100 is connected to the direct-current voltage input terminal 109 (FIG. 4), whereby an inverter that converts direct-current power into alternating-current power functions.

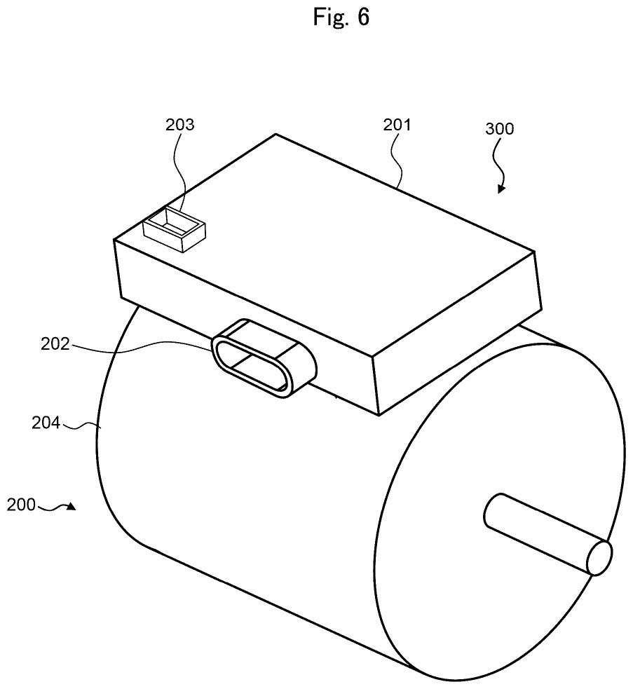

### (FIG. 6)

The inverter 300 is housed in an inverter case 201 together with a motor control substrate, an EMC filter, and a gate drive substrate (not illustrated). Connection of the battery 100 (FIG. 5) outside the inverter 300 and an inverter power supply connector 202 by a harness leads to connection of the battery and the direct-current voltage input terminal 109, resulting in input of direct-current power to the inverter 300.

In addition, a cable for transmitting a signal for exchanging information with a vehicle provided with the inverter 300 and the motor 200 and for controlling the inverter 300 is connected to an inverter signal connector 203 to control the inverter 300 and exchange information with the vehicle. The inverter case 201 is connected to a motor case 204, and a motor output terminal of the inverter 300 and a three-phase alternating-current wiring of the motor 200 are connected by an alternating-current wiring cable (not illustrated). Although not illustrated, the present invention assumes a single-sided cooling inverter.

As described in the foregoing, by using the low-inductance three-phase inverter circuit 101 to which the present invention is applied, a magnitude of a surge voltage generated at the time of switching is suppressed, a switching speed is improved, and a switching loss is accordingly reduced, so that a system efficiency of the inverter 300 is improved to enhance reliability. In addition, not only the lengths of the wires 8a and 8b are changed as the wires 8a and 8b are closer to the connection region 6 or the negative electrode terminal 5, but also the wires 8a and 8b are arranged so as to alternately connect the wiring boards, so that it is possible to achieve both low inductance and equal inductance.

According to the embodiment of the present invention described in the foregoing, the following operations and effects are achieved.

(1) The semiconductor device 104 is provided in the inverter 300 and includes, on the insulation layer 20 of the substrate included in the semiconductor device 104, the positive electrode wiring board 1 provided with the positive electrode terminal 4, the negative electrode wiring board 2 provided with the negative electrode terminal 5, and the alternating-current wiring board 3 provided with the alternating-current terminal 9. The positive electrode wiring board 1 has the plurality of upper arm semiconductor elements 7a electrically connected in parallel, and the alternating-current wiring board 3 has the plurality of lower arm semiconductor elements 7b electrically connected in parallel. The plurality of upper arm semiconductor elements 7a and the alternating-current wiring board 3 are electrically connected to each other by the first wiring members 8a, respectively, and the plurality of lower arm semiconductor elements 7b and the negative electrode wiring board 2 are electrically connected to each other by the second wiring members 8b, respectively. The alternating-current wiring board 3 has the first region 3a to which the first wiring members 8a are connected, the second region 3b in which the plurality of lower arm semiconductor elements 7b are provided, and the connection region 6 that connects the first region 3a and the second region 3b. The connection region 6 is provided at a position opposite to the positive electrode terminal 4 and the negative electrode terminal 5 with a region in between where the first wiring member 8a connects the positive electrode wiring board 1 and the first region 3a and a region in between where the second wiring member 8b connects the negative electrode wiring board 2 and the second region 3b. The positive electrode wiring board 1, the negative electrode wiring board 2, the first region 3a, and the second region 3b are arranged on the insulation layer 20 in the order of the positive electrode wiring board 1, the negative electrode wiring board 2, the first region 3a, and the second region 3b. This configuration enables provision of the semiconductor device 104 achieving both low inductance and equal inductance.

(2) The first wiring members 8a and the second wiring members 8b are alternately arranged. With this configuration, the effect of reducing an inductance of the semiconductor device 104 is increased.

(3) The first wiring member 8a is longer as it is closer to the connection region 6, and the second wiring member 8b is longer as it is closer to the negative electrode terminal 5. Thus, a total inductance is equalized between the semiconductor elements 7a and 7b.

(4) The inverter 300 includes the semiconductor devices 104, and the semiconductor devices 104 are arranged side by side in parallel with a short-dimension direction of the semiconductor device 104, and are connected to the direct-current voltage input terminal 109 via the smoothing capacitor element 102. In this way, the magnitude of the surge voltage generated at the time of switching is suppressed, the switching speed is improved, and the switching loss is accordingly reduced, so that the system efficiency of the inverter 300 is improved to enhance reliability.

Note that the present invention is not limited to the above embodiment, and various modifications and other configurations can be combined without departing from the gist of the present invention. In addition, the present invention is not limited to one including all the configurations described in the above embodiment, and includes one in which a part of the above configurations is removed.

### REFERENCE SIGNS LIST

1 positive electrode wiring board
2 negative electrode wiring board
3 alternating-current wiring board
3a first region
3b second region
4 positive electrode terminal
5 negative electrode terminal
6 connection region
7a semiconductor element (upper arm)
7b semiconductor element (lower arm)
8a wire (first wiring member)
8b wire (second wiring member)
9 alternating-current terminal
10 (direction of) current
20 insulation layer
21 conductor layer
23a upper arm semiconductor element
23b lower arm semiconductor element
101 three-phase inverter circuit
102 smoothing capacitor
103 control circuit
104 semiconductor device
105 gate resistor
106 high-voltage side input wiring
107 low-voltage side input wiring
108 1-leg inverter
109 direct-current voltage input terminal
110 motor output terminal
111 film capacitor
200 motor
201 inverter case
202 inverter power supply connector
203 inverter signal connector
204 motor case
300 inverter

1. A semiconductor device provided in an inverter, the semiconductor device comprising:
a positive electrode wiring board provided with a positive electrode terminal;
a negative electrode wiring board provided with a negative electrode terminal; and
an alternating-current wiring board provided with an alternating-current terminal, on an insulation layer of a substrate included in the semiconductor device,
wherein the positive electrode wiring board has a plurality of upper arm semiconductor elements electrically connected in parallel,
the alternating-current wiring board has a plurality of lower arm semiconductor elements electrically connected in parallel,
the plurality of upper arm semiconductor elements and the alternating-current wiring board being electrically connected to each other by first wiring members, respectively, and
the plurality of lower arm semiconductor elements and the negative electrode wiring board being electrically connected to each other by second wiring members, respectively,
the alternating-current wiring board has a first region to which the first wiring members are connected, a second region in which the plurality of lower arm semiconductor elements are provided, and a connection region that connects the first region and the second region,
the connection region being provided at a position opposite to the positive electrode terminal and the negative electrode terminal with a region in between where the first wiring member connects the positive electrode wiring board and the first region and a region in between where the second wiring member connects the negative electrode wiring board and the second region, and
the positive electrode wiring board, the negative electrode wiring board, the first region, and the second region are arranged on the insulation layer in the order of the positive electrode wiring board, the negative electrode wiring board, the first region, and the second region.

2. The semiconductor device according to claim 1, wherein the first wiring members and the second wiring members are alternately arranged.

3. The semiconductor device according to claim 1, wherein
the first wiring member is longer as the first wiring member is closer to the connection region, and
the second wiring member is longer as the second wiring member is closer to the negative electrode terminal.

4. An Inverter comprising the semiconductor devices according to claim 1,
wherein the semiconductor devices are arranged side by side in parallel with a short-dimension direction of the semiconductor device, and are connected to a direct-current voltage input terminal via a smoothing capacitor element.
